(19) United States
(12) Patent Application Publication
(10) Pub. No.: US 2007/0034953 A1
(43) Pub. Date: Feb. 15, 2007

(54) Semiconductor device and method of fabricating same

(75) Inventor: Amane Oishi, Kanagawa (JP)

Correspondence Address: FOLEY AND LARDNER LLP;SUITE 500, 3000 K STREET NW, WASHINGTON, DC, 20007, US

(73) Assignee: Kabushiki Kaisha Toshiba

(21) Appl. No.: 11/501,236

(22) Filed: Aug. 9, 2006

(30) Foreign Application Priority Data
Aug. 9, 2005 (JP) 2005-230665
Aug. 4, 2006 (JP) 2006-213630

(51) Int. Cl. H01L 27/12

(52) U.S. Cl. 257/347

(57) ABSTRACT

A semiconductor device includes: a semiconductor substrate; a first transistor including a first gate electrode including a first metallic silicide layer, the first gate electrode being formed on the semiconductor substrate through a first gate insulating film, a first gate sidewall insulating film formed on a side face of the first gate electrode, and first impurity regions formed in the semiconductor substrate, the first gate electrode being formed between the first impurity regions; and a second transistor including a second gate electrode including a second metallic silicide layer, the second gate electrode being formed on the semiconductor substrate through a second gate insulating film, a second gate sidewall insulating film having a height, from the semiconductor substrate, lower than that of the first gate sidewall insulating film, the second gate sidewall insulating film being formed on a side face of the second gate electrode, and second impurity regions formed in the semiconductor substrate, the second gate electrode being formed between the second impurity regions.

### CROSS-REFERENCE TO RELATED APPLICATIONS

This application is based upon and claims the benefit of priority from prior Japanese Patent Application No. 2005-230665, filed Aug. 9, 2005, the entire contents of which are incorporated herein be reference.

### BACKGROUND OF THE INVENTION

The present invention relates to a semiconductor device and a method of fabricating same, and more particularly to a semiconductor device including a plurality of transistors having different threshold values, respectively, and a method of fabricating same.

In recent years, power consumption of semiconductor devices has increased due to promotion of high integration and a high operating speed accompanying scale down of the semiconductor devices. Then, a Fully Depleted SOI-MOS field effect transistor (FDSOI-MOSFET) which has high performance and low power consumption, and which has high design affinity with a bulk MOS field effect transistor (bulk MOSFET) is expected as a low power consumption power device of the next generation.

Since a gate electrode is required to have a work function (φm) near a mid gap when the FDSOI-MOSFET is fabricated, a metal gate is normally used.

On the other hand, it has been known that it is difficult to control a threshold value by implantation of impurities into a channel because in the FDSOI-MOSFET, an SOI layer on a silicon oxide film must be thinned as compared with the case of a Partially Depleted SOI (PDSOI) MOSFET or the like and therefore the implantation of impurities into the channel is not so effective.

For this reason, when a plurality of MOSFETs having different threshold values, respectively, are embedded, the threshold values must be controlled by forming metal gates having work functions φm corresponding to respective threshold values in respective MOSFETs.

There has been reported a technique for forming metal gates made of different kinds of metals for MOSFETs, respectively, in order to change threshold values of the metal gates of the respective MOSFETs in such a manner. This technique, for example, is disclosed in Japanese Patent KOKAI. No. 11-261071.

However, there is encountered such a problem that it is technically very difficult to embed the metal gates made of different kinds of metals, respectively, in the prior art.

### BRIEF SUMMARY OF THE INVENTION

A semiconductor device according to one embodiment of the present invention includes:

a semiconductor substrate;

a first transistor comprising a first gate electrode including a first metallic silicide layer, the first gate electrode being formed on the semiconductor substrate through a first gate insulating film, a first gate sidewall insulating film formed on a side face of the first gate electrode, and first impurity regions formed in the semiconductor substrate, the first gate electrode being formed between the first impurity regions; and

a second transistor comprising a second gate electrode including a second metallic silicide layer contacting at least a part of a second gate insulating film, the second gate electrode being formed on the semiconductor substrate through the second gate insulating film, a second gate sidewall insulating film comprising a height, from the semiconductor substrate, lower than that of the first gate sidewall insulating film, the second gate sidewall insulating film being formed on a side face of the second gate electrode, and second impurity regions formed in the semiconductor substrate, the second gate electrode being formed between the second impurity regions.

A semiconductor device according to another embodiment of the present invention includes:

a semiconductor substrate;

a first transistor comprising a first gate electrode including a first metallic silicide layer, the first gate electrode being formed on the semiconductor substrate through a first gate electrode, a first gate sidewall insulating film formed on a side face of the first gate electrode, and first impurity regions formed in the semiconductor substrate, the first gate electrode being formed between the first impurity regions; and

a second transistor comprising a second gate electrode including a second metallic silicide layer, the second gate electrode being formed on the semiconductor substrate through a second gate insulating film, a second gate sidewall insulating film comprising a height, from the semiconductor substrate, lower than that of the first gate sidewall insulating film, the second gate sidewall insulating film being formed on a side face of the second gate electrode, and second impurity regions formed in the semiconductor substrate, the second gate electrode being formed between the second impurity regions.

A method of fabricating a semiconductor device according to still another embodiment of the present invention includes:

preparing a semiconductor substrate;

forming a first transistor comprising a first gate electrode, the first gate electrode being insulated by a first gate sidewall insulating film, and a second transistor comprising a second gate electrode insulated by a second gate sidewall insulating film comprising a height lower than that of the first gate sidewall insulating film on the semiconductor substrate;

covering the first and second sidewall gate insulating films, and the first and second gate electrodes with a metal film; and

heating the first and second gate electrodes, and the metal film to form metallic silicide layers in the first and second gate electrodes, respectively.

### BRIEF DESCRIPTION OF THE DRAWINGS

FIGS. 1A to 1F are respectively cross sectional views showing processes for fabricating a semiconductor device according to a first embodiment of the present invention;

FIGS. 2A to 2E are respectively cross sectional views showing processes for fabricating a semiconductor device according to a second embodiment of the present invention;

FIG. 3 is a cross sectional view of a semiconductor device according to a third embodiment of the present invention; and

FIG. 4 is a cross sectional view of a semiconductor device according to a fourth embodiment of the present invention.

### DETAILED DESCRIPTION OF THE INVENTION

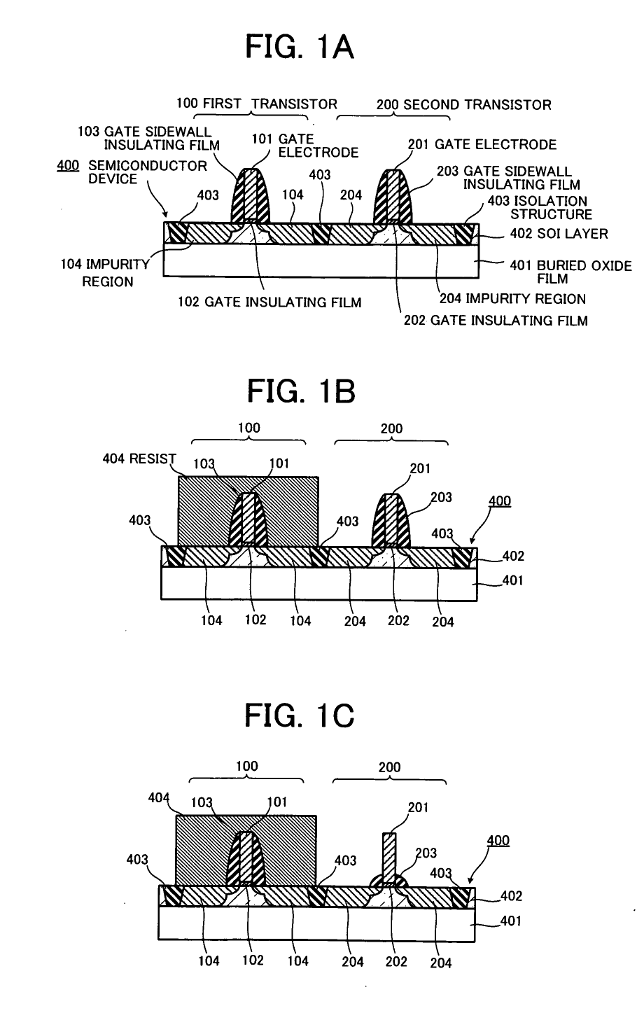

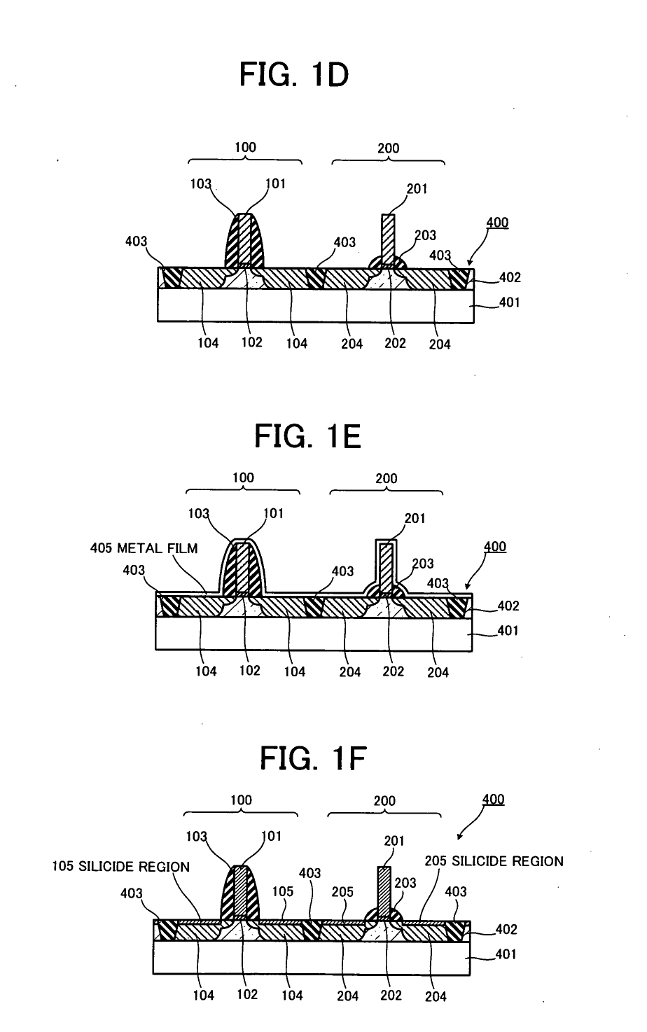

FIGS. 1A to 1F are respectively cross sectional views showing processes for fabricating a semiconductor device according to a first embodiment of the present invention.

Firstly, a semiconductor device as shown in FIG. 1A is fabricated. A structure of a semiconductor device 400 in FIG. 1A will be described as follows. A buried oxide film 401 made of SiO₂ is formed on a silicon supporting substrate (not shown), and an SOI layer 402, made of single crystal silicon, containing impurity regions 104 and 204 is formed on the buried oxide film 401. Gate electrodes 101 and 201 each of which is made of, e.g., polysilicon are formed on the SOI layer 402 through gate insulating films 102 and 202 each of which is made of, e.g., SiON, respectively. Gate sidewall insulating films 103 and 203 are formed on side faces of the gate electrodes 101 and 201, respectively. Moreover, an isolation structure 403 which, for example, has a shallow trench isolation (STI) structure is formed in the SOI layer 402 to isolate a first transistor 100 and a second transistor 200 from each other.

Impurity regions 104 and 204 are made by the implanting of impurity ions to SOI layer 402. Here, n-type impurity ions, e.g., As or P are used as impurity ions in n-type MOSFET, and p-type impurity ions, e.g., B or In are used as impurity ions in p-type MOSFET.

Although not illustrated in the figures, a single layer structure (made of, e.g., SiN or the like), a two layer structure (made of, e.g., SiN and SiO₂), or a structure having three or more layers may also be adopted as a structure of each of the gate sidewall insulating films 103 and 203.

Here, the gate electrode 101 and the gate electrode 201 correspond to a first gate electrode and a second gate electrode which are defined in claim 1, respectively. The gate insulating film 102 and the gate insulating film 202 correspond to a first gate insulating film and a second gate insulating film which are defined in claim 1 and claim 10, respectively. Also, the gate sidewall insulating film 103 and the gate sidewall insulating film 203 correspond to a first gate sidewall insulating film and a second gate sidewall insulating film which are defined in claim 1 and claim 10, respectively. Farther, the impurity region 104 and the impurity region 204 correspond to first impurity regions and second impurity regions which are defined in claim 1 and claim 10, respectively.

Next, as shown in FIG. 1B, the first transistor 100 is covered with a resist 404 through a photolithography process.

Next, as shown in FIG. 1C, the gate sidewall insulating film 203 of the second transistor 200 is selectively etched away by utilizing an anisotropic etching method to lower its height.

Next, as shown in FIG. 1D, the resist 404 with which the first transistor 100 is covered is removed.

Next, as shown in FIG. 1E, a suitable metal is sputtered over the overall surface of the semiconductor device 400 to form a metal film 405. Here, Ni, Pt, Co, Er, NiPt or the like is given as the metal of which the metal film 405 is made.

Next, when a heat treatment is performed, the metal is injected from the metal film 405 to the gate electrodes 101 and 201, and impurity regions 104 and 204 in the SOI layer 402, thereby causing a silicidization reaction to occur. At this time, a side face of the gate electrode 101 of the first transistor 100 is almost perfectly covered with the gate sidewall insulating film 103, whereas a side face of the gate electrode 201 of the second transistor 200 is partially exposed because the height of the gate sidewall insulating film 203 is lowered by the anisotropic etching. For this reason, the gate electrode 201 having a large area through which the gate electrode 201 contacts the metal film 405 is more remarkably silicidized than the gate electrode 101, and thus the gate electrode 201 is fully silicidized. Here, the full silicidization means a state in which at least a part of a silicide layer contacts a gate insulating film.

Incidentally, the gate electrode 101 of the first transistor 100 may be fully silicidized, or only an upper portion thereof may be silicidized. In either case, however, a ratio of the metal to silicon in the gate electrode 101 becomes smaller than that in the gate electrode 201.

Next, as shown in FIG. 1F, when the residual metal film 405 is removed, there is obtained the semiconductor device 400 including the gate electrode 201 all of which are silicidized, the gate electrode 101 a part of or all of which are silicidized, and silicide regions 105 and 205 which are formed by silicidizing exposed surfaces of an upper portion of impurity regions 104 and 204 in the SOI layer 402.

After that, although not illustrated in the figures, a protective insulating film made of, e.g., SiN is formed over the overall surface of the semiconductor device 400, an interlayer insulating film made of, e.g., SiO₂ is deposited on the protective insulating film thus formed, and a wiring is formed in the interlayer insulating film, thereby completing the semiconductor device 400.

According to the first embodiment of the present invention, the gate electrodes are silicidized after the heights of the gate sidewall insulating film included in the two transistors, respectively, are changed, whereby the threshold values of the two transistors can be individually controlled since the rates of the metal contained in the gate electrodes, respectively, are changed.

Incidentally, although the first embodiment of the present invention can be applied to both a Partially Depleted Silicon on Insulator (PDSOI) semiconductor device and a Fully Depleted Silicon on Insulator (FDSOI) semiconductor device, it is more effective to apply the first embodiment of the present invention to the FDSOI semiconductor device in which it is difficult to control the threshold value by the implantation of the impurities into the channel because of thinness of the SOI layer.

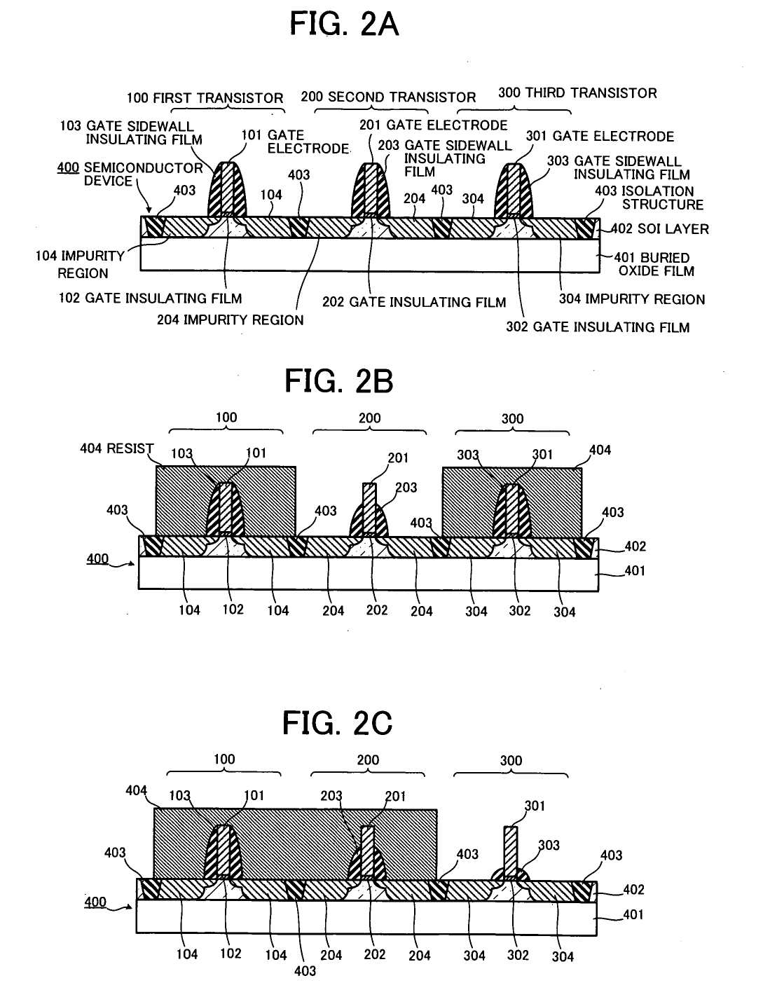

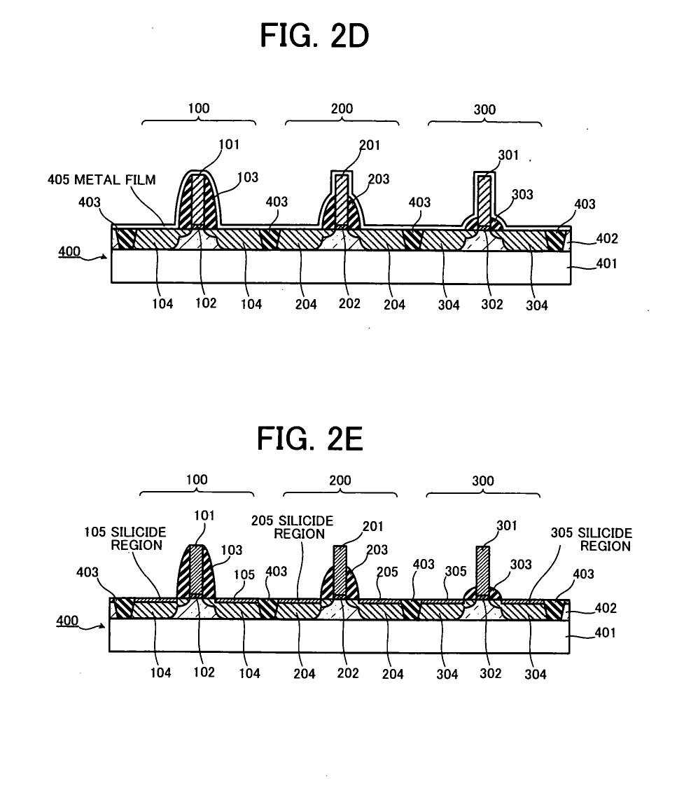

FIGS. 2A to 2E are respectively cross sectional views showing processes for fabricating a semiconductor device according to a second embodiment of the present invention. The description has been given in the first embodiment with respect to the case where the semiconductor device has the two transistors, whereas in the second embodiment, a description will be given below with respect to the case where a semiconductor device has three transistors. Incidentally, since the materials or the like of the constituent portions are the same as those in the first embodiment, its description is omitted here for the sake of simplicity.

Firstly, a semiconductor device 400 as shown in FIG. 2A is fabricated. A structural difference between the semiconductor device 400, shown in FIG. 1A, according to the first embodiment and the semiconductor device 400, shown in FIG. 2A, according to the second embodiment is that a third transistor 300 is formed in addition to the first transistor 100 and the second transistor 200.

Next, as shown in FIG. 2B, the first transistor 100 and the third transistor 300 are covered with the resist 404 through the photolithography process, and the gate sidewall insulating film 203 of the second transistor 200 is selectively etched away by utilizing the anisotropic etching method to lower its height.

Here, the anisotropic etching is performed such that the gate sidewall insulating film 203 of the second transistor 200 has the height, from the semiconductor substrate, lower than that of the gate sidewall insulating film 103 of the first transistor 100.

Next, as shown in FIG. 2C, the first transistor 100 and the second transistor 200 are covered with the resist 404 through the photolithography process, and the gate sidewall insulating film 303 of the third transistor 300 is selectively etched away by utilizing the anisotropic etching method to lower its height.

Here, the anisotropic etching is performed such that the gate sidewall insulating film 303 of the third transistor 300 has the height, from the semiconductor substrate, lower than that of the gate sidewall insulating film 203 of the second transistor 200.

Next, after the resist 404 is removed, as shown in FIG. 2D, a suitable metal is sputtered over the overall surface of the semiconductor device 400 to form a metal film 405.

Next, when the heat treatment is performed, the metal is injected from the metal film 405 to the gate electrodes 101, 201 and 301, and impurity regions 104, 204 and 304 in the SOI layer 402, thereby causing the silicidization reaction to occur. At this time, the side face of the gate electrode 101 of the first transistor 100 is almost perfectly covered with the gate sidewall insulating film 103. The side face of the gate electrode 201 of the second transistor 200 is partially exposed since the height of the gate sidewall insulating film 203 is lowered by the anisotropic etching. Also, a side face of the gate electrode 301 of the third transistor 300 is more largely exposed than the side face of the gate electrode 201 of the second transistor 200 is partially exposed since the height of the gate sidewall insulating film 303 is lower than that of the gate sidewall insulating film 203. For this reason, a rate of the silicidization increases in the order of the gate electrode 101, the gate electrode 201 and the gate electrode 301. Here, the gate electrode 301 and the gate electrode 201 are fully silicidized.

Incidentally, the gate electrode 101 of the first transistor 100 may be fully silicidized, or only a part thereof may be silicidized. In either case, however, the ratio of the metal to silicon increases in the order of the gate electrode 101, the gate electrode 201 and the gate electrode 301.

Next, when the residual metal film 405 is removed, as shown in FIG. 2E, there is obtained the semiconductor device 400 including the gate electrodes 201 and 301 which are fully silicidized, the gate electrode 101 which are partially or fully silicidized, and silicide regions 105, 205 and 305 which are formed by silicidizing exposed surfaces of an upper portion of impurity regions 104, 204 and 304 in the SOI layer 402.

After that, although not illustrated in the figures, the protective insulating film is formed over the overall surface of the semiconductor device 400, the interlayer insulating film is deposited on the protective insulating film thus formed, and the wiring is formed in the interlayer insulating film, thereby completing the semiconductor device 400.

According to the second embodiment of the present invention, even when it is required to embed the three transistors having different three threshold values, respectively, the three gate electrodes are silicidized after the heights of the three gate sidewall insulating films included in the three transistors, respectively, are changed, whereby the threshold values of the three transistors are individually controlled by changing the rates of the metal contained in the three gate electrodes, respectively. As a result, it is possible to realize the embedding of three transistors having different three thresholds, respectively, in the semiconductor device. Incidentally, it is to be understood that it is possible to form the transistors having different four or more threshold values, respectively.

Incidentally, although the second embodiment of the present invention can be applied to both the PDSOI semiconductor device and the FDSOI semiconductor device, it is more effective to apply the second embodiment of the present invention to the FDSOI semiconductor device in which it is difficult to control the threshold value by the implantation of the impurities into the channel because of thinness of the SOI layer.

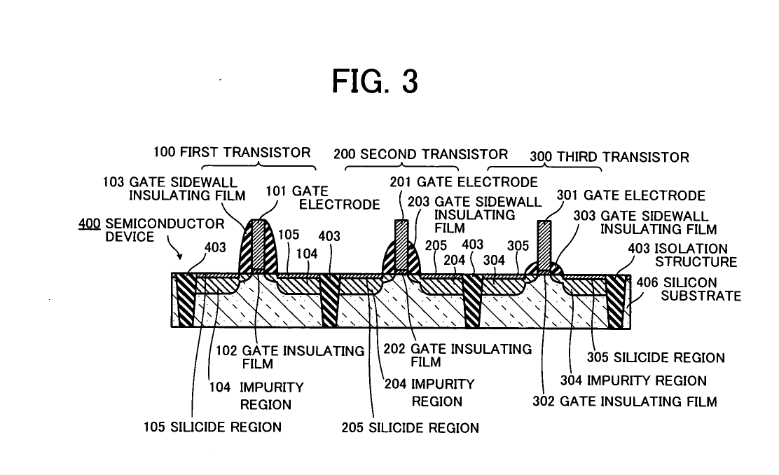

FIG. 3 is a cross sectional view of a semiconductor device according to a third embodiment of the present invention. The description has been given in each of the first and second embodiments with respect to the case where the semiconductor device has the SOI structure, whereas in the third embodiment, a description will be given below with respect to the case where a semiconductor device has a bulk structure. Incidentally, a description with respect to constituent portions containing the same materials or the like as those in the constituent portions of the first embodiment is omitted here for the sake of simplicity.

A structure of a semiconductor device 400 according to the third embodiment of the present invention will be described as follows. The gate electrodes 101, 201 and 301 are formed on a silicon substrate 406, made of single crystal silicon, containing impurity regions 104, 204 and 304 through the gate insulating films 102, 202 and 302, respectively, and the gate sidewall insulating films 103, 203 and 303 are formed on the side faces of the gate electrodes 101, 201 and 301, respectively. Moreover, isolation structures 403 are formed in the silicon substrate 406, thereby isolating the first transistor 100, the second transistor 200 and the third transistor 300 from one another. Also, silicide regions 105, 205 and 305 are formed in exposed surfaces of an upper portion of impurity regions 104, 204 and 304 in the silicon substrate 406. Incidentally, any of the protective insulating film, the interlayer insulating film, the wiring and the like which are formed as upper layers with respect to the illustrated portions is not illustrated in FIG. 3.

The heights of the gate sidewall insulating films of the three transistor decreases in the order of the gate sidewall insulating film 103 of the first transistor 100, the gate sidewall insulating film 203 of the second transistor 200, and the gate sidewall insulating film 303 of the third transistor 300. In accordance with this structure, the rates of the metal contained in the gate electrodes 101, 201 and 301 of the first, second and third transistors 100, 200 and 300, respectively, increases in the order of the gate electrode 101 of the first transistor 100, the gate electrode 201 of the second transistor 200, and the gate electrode 301 of the third transistor 300.

According to the third embodiment of the present invention, even when the three transistors having the different three threshold values, respectively, are embedded in the semiconductor device having the bulk structure, the gate electrodes are silicidized after the heights of the gate sidewall insulating films included in the three transistors, respectively, are changed, whereby the threshold values of the respective transistors are, individually controlled by changing the rates of the metal contained in the respective gate electrodes. As a result, it is possible to realize the embedding of the three transistors having the different three threshold values, respectively, in the semiconductor device having the bulk structure. Incidentally, it is to be understood that it is possible to form the transistors having different two or four or more threshold values similarly to each of the cases of the first and second embodiments.

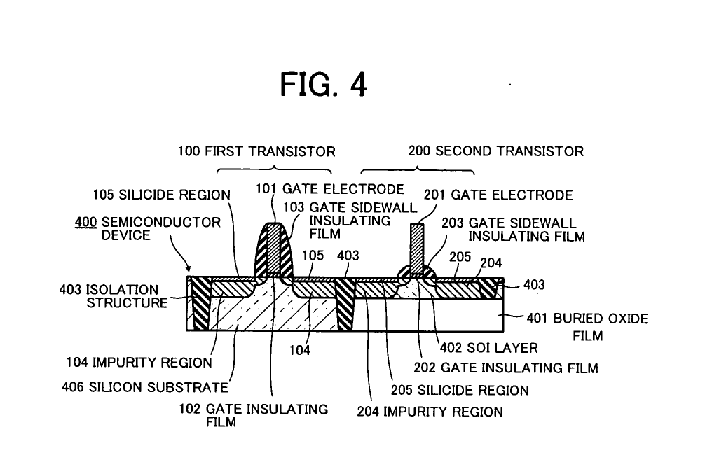

FIG. 4 is a cross sectional view of a semiconductor device according to a fourth embodiment of the present invention. In the fourth embodiment, a description will be given below with respect to the case where a semiconductor device includes both a transistor having the SOI structure and a transistor having the bulk structure. Incidentally, a description with respect to constituent portions containing the same materials or the like as those in the constituent portions of each of the first and third embodiments is omitted here for the sake of simplicity.

A structure of a semiconductor device 400 according to the fourth embodiment of the present invention will be described as follows. In a first transistor 100 region, the gate electrode 101 is formed on the silicon substrate 406 containing the impurity region 104 through the gate insulating film 102, and the gate sidewall insulating film 103 is formed on the side face of the gate electrode 101. On the other hand, in a second transistor 200 region, the buried oxide film 401 is formed on the silicon supporting substrate (not shown), the SOI layer 402 containing the impurity region 204 is formed on the buried oxide film 401, the gate electrode 201 is formed on the SOI layer 402 through the gate insulating film 202, and the gate sidewall insulating film 203 is formed on the side face of the gate electrode 201. Moreover, the isolation structures 403 are formed in the silicon substrate 406 and the SOI layer 402, thereby isolating the first transistor 100 and the second transistor 200 from each other. Also, silicide regions 105 and 205 are formed on exposed surfaces of upper portions of impurity regions 104 and 204, respectively. Incidentally, any of the protective insulating film, the interlayer insulating film, the wiring and the like which are formed as upper layers with respect to the illustrated portions is not illustrated in FIG. 4.

The height of the gate sidewall insulating film 203 of the second transistor 200 is lower than that of the gate sidewall insulating film 103 of the first transistor 100. In accordance with this structure, the rate of the metal contained in the gate electrode 201 of the second transistor 200 is larger than that of the metal contained in the gate electrode 101 of the first transistor 100.

According to the fourth embodiment of the present invention, even when both the transistor having the SOI structure and the transistor having the bulk structure are embedded in the semiconductor device so as to have different threshold values, the gate electrodes are silicidized after the heights of the gate sidewall insulating films included in the respective transistors are changed, whereby the threshold values of the respective transistors are individually controlled by changing the rates of the metal contained in the respective gate electrodes. As a result, it is possible to realize the embedding of the transistor, having the SOI structure, and the transistor, having the bulk structure, which are different in threshold value from each other in the semiconductor device.

It should be noted that each of the above-mentioned embodiments is merely an embodiment, the present invention is not intended to be limited to those embodiments, and the various changes can be implemented without departing from the gist of the invention. For example, although each of the above-mentioned embodiments has been described based on two or three transistors having different threshold values, respectively, any number of transistors may also be included in the semiconductor device. In addition, a combination of heights of gate sidewall insulating films of respective transistors is not limited to any of the combinations as described above.

What is claimed is:

1. A semiconductor device, comprising:
a semiconductor substrate;
a first transistor comprising a first gate electrode including a first metallic silicide layer, the first gate electrode being formed on the semiconductor substrate through a first gate insulating film, a first gate sidewall insulating film formed on a side face of the first gate electrode, and first impurity regions formed in the semiconductor substrate, the first gate electrode being formed between the first impurity regions; and
a second transistor comprising a second gate electrode including a second metallic silicide layer contacting at least a part of a second gate insulating film, the second gate electrode being formed on the semiconductor substrate through the second gate insulating film, a second gate sidewall insulating film comprising a height, from the semiconductor substrate, lower than that of the first gate sidewall insulating film, the second gate sidewall insulating film being formed on a side face of the second gate electrode, and second impurity regions formed in the semiconductor substrate, the second gate electrode being formed between the second impurity regions.

2. A semiconductor device according to claim 1, wherein:
a rate of a metal contained in the second gate electrode is higher than that of the metal contained in the first gate electrode.

3. A semiconductor device according to claim 2, wherein:
the first metallic silicide layer of the first gate electrode contacts at least a part of the first gate insulating film.

4. A semiconductor device according to claim 1, wherein:
each of the first transistor and the second transistor has a Fully Depleted SOI (FDSOI) structure.

5. A semiconductor device according to claim 1, wherein:
the first transistor has a bulk structure, and
the second transistor has an FDSOI structure.

6. A semiconductor device according to claim 1, wherein:
each of the first transistor and the second transistor has a Partially Depleted SOI (PDSOI) structure.

7. A semiconductor device according to claim 1, wherein:
each of the first transistor and the second transistor has a bulk structure.

8. A semiconductor device according to claim 1, wherein:
each of the first metallic silicide layer of the first gate electrode and the second metallic silicide layer of the second gate electrode contains therein at least one selected from a group consisting of Ni, Pt, Co, Er and NiPt.

9. A semiconductor device according to claim 1, wherein:
each of the first gate insulating film and the second gate insulating film contains therein at least one of SiN and SiO₂.

10. A semiconductor device, comprising:
a semiconductor substrate;
a first transistor comprising a first gate electrode including a first metallic silicide layer, the first gate electrode being formed on the semiconductor substrate through a first gate electrode, a first gate sidewall insulating film formed on a side face of the first gate electrode, and first impurity regions formed in the semiconductor substrate, the first gate electrode being formed between the first impurity regions; and
a second transistor comprising a second gate electrode including a second metallic silicide layer, the second gate electrode being formed on the semiconductor substrate through a second gate insulating film, a second gate sidewall insulating film comprising a height, from the semiconductor substrate, lower than that of the first gate sidewall insulating film, the second gate sidewall insulating film being formed on a side face of the second gate electrode, and second impurity regions formed in the semiconductor substrate, the second gate electrode being formed between the second impurity regions.

11. A method of fabricating a semiconductor device, comprising:
preparing a semiconductor substrate;
forming a first transistor comprising a first gate electrode, the first gate electrode being insulated by a first gate sidewall insulating film, and a second transistor comprising a second gate electrode insulated by a second gate sidewall insulating film comprising a height lower than that of the first gate sidewall insulating film on the semiconductor substrate;
covering the first and second sidewall gate insulating films, and the first and second gate electrodes with a metal film; and
heating the first and second gate electrodes, and the metal film to form metallic silicide layers in the first and second gate electrodes, respectively.

12. A method of fabricating a semiconductor device according to claim 11, wherein:
the metallic silicide layers are formed such that a rate of the metallic silicide layer contained in the second gate electrode is made higher than that of the metallic silicide layer contained in the first gate electrode.

13. A method of fabricating a semiconductor device according to claim 12, wherein:
the metallic silicide layers in the second gate electrode are formed so as to contacts at least a part of the second gate insulating film.

14. A method of fabricating a semiconductor device according to claim 13, wherein:
the metallic silicide layers in the first gate electrode are formed so as to contacts at least a part of the first gate insulating film.

15. A method of fabricating a semiconductor device according to claim 11, wherein:
each of the first transistor and the second transistor is formed so as to have an FDSOI structure.

16. A method of fabricating a semiconductor device according to claim 11, wherein:
the first transistor is formed so as to have a bulk structure, and
the second transistor is formed so as to have an FDSOI structure.

17. A method of fabricating a semiconductor device according to claim 11, wherein:
each of the first transistor and the second transistor is formed so as to have a PDSOI structure.

18. A method of fabricating a semiconductor device according to claim 11, wherein:
each of the first transistor and the second transistor is formed so as to have a bulk structure.

19. A method of fabricating a semiconductor device according to claim 11, wherein:
the covering with the metal film employs a metal film containing therein at least one selected from a group consisting of Ni, Pt, Co, Er and NiPt.

20. A method of fabricating a semiconductor device according to claim 11, wherein:
each of the first transistor and the second transistor is formed such that each of the first gate insulating film and the second gate insulating film contains therein at least one of SiN and SiO₂.
